(19) United States
(12) Patent Application Publication
(10) Pub. No.: US 2022/0038093 A1
(43) Pub. Date: Feb. 3, 2022

(54) GATE DRIVER

(71) Applicant: YASA LIMITED, Oxford, Oxfordshire (GB)

(72) Inventors: Simon David HART, Welshpool, Powys (GB); Antony John WEBSTER, Montgomery, Powys (GB)

(21) Appl. No.: 17/297,205

(22) PCT Filed: Nov. 26, 2019
(86) PCT No.: PCT/GB2019/053338

§ 371 Date: May 26, 2021

(30) Foreign Application Priority Data
Nov. 26, 2018 (GB) 1819201.3

(51) Int. Cl. H03K 17/16

(52) U.S. Cl. CPC H03K 17/168; H03K 2217/0081; H03K 17/166

(57) ABSTRACT

A gate driver for a semiconductor power device and a method of driving the gate of a semiconductor power device. The current flowing through the semiconductor power device, caused by a first gate drive voltage during the present switching cycle, is sensed. Based on a second drive signal to be used in the next switching cycle, a second current is determined for that second drive signal, which are then compared to an EMC model. The EMC model defines a plurality of EMC values for respective gate drive voltages and currents conducted through the semiconductor power device. A gate drive voltage adjustment value is selected from a plurality of gate drive voltage adjustment values in the EMC model based on the predicted EMC value generated by the semiconductor power device when being driven using the second drive voltage and conducting the second current. The second gate drive voltage is adjusted using the selected gate drive voltage adjustment value for the next switching cycle.

### FIELD OF THE INVENTION

The present invention relates to power supplies and more particularly to improving efficiency and maximising available power from switching power supplies, by using electromagnetic compatibility as the governing feature.

### BACKGROUND OF THE INVENTION

Losses occur in power semi-conductor devices when transitioning between conduction and insulator states and so transiting quickly is preferable. However fast transitioning can generate electromagnetic emissions (mainly wire bound, with harmonics above ˜30 MHz airborne), which may breach international regulations on EMI (Electromagnetic Interference), and therefore a compromise on rate of transition is sought.

Gate drive circuits are used to control switching of IGBTs, power MOSFETS, diodes and similar devices—and traditionally gate drivers have used a fixed drive characteristic dominated by a fixed value gate resistor that is sized to provide the maximum efficiency while limiting the rate at which the device can change state so as to meet EMC (Electromagnetic Compatibility) standards.

Prior art approaches have sought to control gate drive impedance and deal separately with turn-on and turn-off regions. These approaches often require tuning of individual power supplies and loading conditions and add significant component complexity and cost.

Kuroda JP2009065483 and corresponding US2009066375 seeks to control turn-on/turn-off switching speed of a MOS transistor by using two voltage clip circuits on the output which are fed back to a gate terminal of the MOS transistor and thereby achieves “a high-linearity elevation slew rate” on switch on and off. This approach controls switch rate by controlling the time constants of resistors and gate-drain capacitance. Over voltages are clipped to a pre-set value, which may vary between devices and so efficiency is averaged across multiple units. This approach comes with the challenge of added complexity/cost and compromise on averaged efficiency across switch devices

In a similar way Vinod U.S. Pat. No. 6,208,185 again uses two separate control circuits to optimise three stages of switching during turn on and three stages of switching during turn off. The first circuit rapidly charges the gate of an IGBT (Insulated Gate Bipolar Transistor) to the threshold gate voltage level at which point a second circuit provides a controlled charging of the gate to control di/dt and then the first circuit re-applies to rapidly reach a full turn-on state thereby reducing power loss during turn on. A similar format is used to control turn off. This approach typifies many where the action of turning on and off a semiconductor switch is divided in to several time periods, each individually controlled to minimise losses and yet control transient rates to reduce noise. These gate drive circuits are complex and costly.

Pace WO2005104743 uses a field programmable gate array (FPGA) to store parameters and equations for a control signal that is used to control the turn-on /off behaviour of an IGBT device. The control circuitry receives real-time current, voltage and temperature data during operation and compares these values with data stored in the FPGA sending the corresponding parameters to the gate drive circuit. The gate drive modifies the signal on the gate of the IGBT accordingly and thereby optimizes the turn-on and/or turn-off behaviour of the device based on actual operating conditions.

Pace WO2005104743 teaching is directed towards optimising the turn on and off behaviour of semiconducting switch devices by using a look up table, but data is derived from switch behaviour and not load and is used to optimise di/dt, dv/dt and switch temperature characteristics which can mean EMC is compromised.

We have therefore seen that a simple low cost approach is required for high efficiency gate switching which accommodate EMC requirements, which though widely applicable, particular advantage may be found in easily accommodating changes in vehicle configuration e.g. for various hybrid or all electric vehicle topologies/types.

### SUMMARY OF THE INVENTION

The present invention provides a gate driver for driving the gate of a semiconductor power device, comprising: a gate power supply for supplying power to the gate of the semiconductor power device; a gate input for receiving a gate drive signal; one or more current sensors for sensing the current flowing through the semiconductor power device; a controller having an input coupled to the one or more current sensors for receiving a measurement of the current flowing through the semiconductor power device, and an output coupled to the gate power supply for controlling the gate power supply, wherein the controller is configured to: sense a first current flowing through the semiconductor power device during the present switching cycle when the gate of the semiconductor power device is driven with a first gate drive voltage; determine a second current conducted by the semiconductor power device based on a second gate drive voltage to drive the gate of the semiconductor power device for a next switching cycle; compare the second current with an Electromagnetic Compliance (EMC) model, the EMC model defining a plurality of EMC values for respective gate drive voltages and currents conducted through the semiconductor power device; selecting a gate drive voltage adjustment value from a plurality of gate drive voltage adjustment values in the EMC model; adjusting the second gate drive voltage using the selected gate drive voltage adjustment value for the next switching cycle, wherein the gate drive voltage adjustment value is selected from a plurality of gate drive voltage adjustment values in the EMC model based on the predicted EMC value generated by the semiconductor power device when being driven using the second drive voltage and conducting the second current.

The present invention seeks to control the switch rate and turn-on/turn-off rates, by using a predicted load current and knowledge of EMC requirements. This enables a the performance of the device to be optimised in terms of power output and/or efficiency within the confines of defined EMC limits.

The gate drive voltage adjustment value may selected such that the predicted EMC value is below a threshold value. The gate drive voltage adjustment value may be selected to maximise a transition speed of the semiconductor power device and/or minimise power losses within the semiconductor power device.

The second gate drive voltage may be adjusted by controlling a voltage supplied to the gate of the semiconductor power device by the gate power supply. The gate power supply may comprise a current source have a voltage feedback loop, and wherein the second gate drive voltage is adjusted by controlling a voltage on the voltage feedback loop. Controlling the voltage supplied to the gate of the semiconductor power device by the gate power supply preferably adjusts the slew rate of the semiconductor power device.

In some gate drivers, prior to the present switching cycle in which the gate of the semiconductor power device is driven with the first gate drive voltage, the controller may be configured to: sense the current flowing through the semiconductor power device due to a gate drive voltage applied to the semiconductor power device gate in the previous switching cycle. In this gate driver, the controller may be configure to: compare the current flowing through the semiconductor power device due to a gate drive voltage applied to the semiconductor power device gate in the previous switching cycle to expected values from the EMC model for the same current and drive voltage; determine a difference between the current flowing through the semiconductor power device due to a gate drive voltage applied to the semiconductor power device gate and the expected values from the EMC model, and using the difference between the current flowing through the semiconductor power device due to a gate drive voltage applied to the semiconductor power device gate and the expected values from the EMC model in order to adjust the gate drive voltage in a later switching cycle.

In other gate drivers, prior to the present switching cycle in which the gate of the semiconductor power device is driven with the first gate drive voltage, the controller may be configured to: sense the voltage between the collector and emitter of the semiconductor power device due to the gate drive voltage applied to the semiconductor power device gate in the previous switching cycle, and compensate for a temperature of the semiconductor device based on the sensed voltage between the collector and emitter, by adjusting the gate power supply voltage based on the sensed voltage between the collector and emitter.

When there is more than one current sensor present in the gate driver, the controller may be configured to compare the sensed currents from each of the current sensors and control the gate voltage power supply in response to the compared sensed currents.

The first current flowing through the semiconductor power device during the present switching cycle when the gate of the semiconductor power device is driven with a first gate drive voltage may represent a first power demanded of the semiconductor power device during the present switching cycle. The determined second current conducted by the semiconductor power device due to the second gate drive voltage to drive the gate of the semiconductor power device for a next switching cycle may represent a second power demanded of the semiconductor power device during the next switching cycle. The first and second powers demanded of the semiconductor power device may be different powers.

The gate drive voltage adjustment value may additionally be selected based on a predicted slew rate of the semiconductor power device for the second current and second gate drive voltage.

In any of the above gate drivers, the controller may be configured to generate the gate drive voltage.

We also describe a power system, comprising: a plurality of semiconductor power devices configured as one or more power switches; and a plurality of gate drivers as described above, each gate driver for driving the gate of respective one or more of the semiconductor power devices. The plurality of controllers of the plurality of gate drivers may be synchronised with a common clock.

The plurality of semiconductor power devices may be configured as a multi-phase and/or multi-power-level inverter. The power system may comprise six controllers, and wherein the semiconductor power devices are configured in a three-phase two-level inverter. The power system may also comprise six power switches, each of the six controllers being coupled to a respective one of the six power switches, each power switch comprising one or more semiconductor power devices.

The present invention also provides A method of driving the gate of a semiconductor power device, comprising: driving the gate of the semiconductor power device with a first gate drive voltage such that it conducts a first current during the present switching cycle; sensing the first current flowing through the semiconductor power device during the present switching cycle; determining a second current conducted by the semiconductor power device based on a second gate drive voltage to drive the gate of the semiconductor power device for a next switching cycle; comparing the second current with an Electromagnetic Compliance (EMC) model, the EMC model defining a plurality of EMC values for respective gate drive voltages and currents conducted through the semiconductor power device; selecting a gate drive voltage adjustment value from a plurality of gate drive voltage adjustment values in the EMC model; adjusting the second gate drive voltage using the selected gate drive voltage adjustment value; and driving the gate of the semiconductor power device using the adjusted second gate drive voltage, wherein the gate drive voltage adjustment value is selected from a plurality of gate drive voltage adjustment values in the EMC model based on the predicted EMC value generated by the semiconductor power device when being driven using the second drive voltage and conducting the second current.

The present invention seeks to control the switch rate and turn-on/turn-off rates, by using a predicted load current and knowledge of EMC requirements. This enables a the performance of the device to be optimised in terms of power output and/or efficiency within the confines of defined EMC limits.

In the method, the gate drive voltage adjustment value may be selected such that the predicted EMC value is below a threshold value. The gate drive voltage adjustment value may be selected to maximise a transition speed of the semiconductor power device and/or minimise power losses with the semiconductor power device.

The second gate drive voltage may be adjusted by controlling a voltage supplied to the gate of the semiconductor power device. Controlling the voltage supplied to the gate of the semiconductor power device by the gate power supply may adjust the slew rate of the semiconductor power device.

Prior to driving the gate of the semiconductor power device with the first gate drive voltage, the method may comprise: sensing the current flowing through the semiconductor power device due to a gate drive voltage applied to the semiconductor power device gate in the previous switching cycle. This method may also comprise: comparing the current flowing through the semiconductor power device due to a gate drive voltage applied to the semiconductor power device gate in the previous switching cycle to expected values from the EMC model determining a difference between the current flowing through the semiconductor power device due to a gate drive voltage applied to the semiconductor power device gate and the expected values from the EMC model, and using the difference between the current flowing through the semiconductor power device due to a gate drive voltage applied to the semiconductor power device gate and the expected values in from the EMC model in order to adjust the gate drive voltage in a later switching cycle.

Prior to driving the gate of the semiconductor power device with the first gate drive voltage, the method may comprise: sensing the voltage between the collector and emitter of the semiconductor power device due to a gate drive voltage applied to the semiconductor power device gate in the previous switching cycle, and compensating for a temperature of the semiconductor device based on the sensed voltage between the collector and emitter, comprising: adjusting the gate voltage based on the sensed voltage between the collector and emitter.

Sensing the first current flowing through the semiconductor power device during the present switching cycle may comprise sensing the current in one or more locations within a circuit comprising the semiconductor power device.

When there are a plurality of semiconductor power devices, the method of driving the gates of the plurality of semiconductor power devices may comprise, for each of the gates for each of the semiconductor power devices, performing the above described methods.

This method may be performed by a plurality of controllers, each controller being associated with a respective one or more of the plurality of semiconductor power devices. In such a case, the plurality of controllers may be synchronised with a common clock.

In any of the above methods, the first current flowing through the semiconductor power device during the present switching cycle when the gate of the semiconductor power device is driven with a first gate drive voltage may represent a first power demanded of the semiconductor power device during the present switching cycle, and the determined second current conducted by the semiconductor power device due to the second gate drive voltage to drive the gate of the semiconductor power device for the next switching cycle may represent a second power demanded of the semiconductor power device during the next switching cycle. The first and second powers demanded of the semiconductor power device may be different to each.

The gate drive voltage adjustment value may be additionally selected based on a predicted slew rate of the semiconductor power device for the second current and second gate drive voltage.

The method may also comprise generating the gate drive voltage, and driving the gate of the semiconductor power device with the gate drive voltage.

In any of the above gate drivers, power systems or methods, the semiconductor power device may comprise an IGBT, Silicon carbide (SiC) semiconducting switch devices, metal oxide semiconducting field effect transistors (MOSFETs), or power diodes.

### LIST OF FIGURES

The present invention will now be described, by way of example only, and with reference to the accompanying figures, in which:

FIG. 1 represents a simplified diagram of a gate driver according to the present invention;

FIG. 2 shows a slew rate of the semiconductor power device; and

FIG. 3 shows a flowchart of the method described herein.

### DETAILED DESCRIPTION OF THE PREFERRED EMBODIMENTS

In brief, we describe a gate driver for a semiconductor power device and a method of driving the gate of a semiconductor power device. The current flowing through the semiconductor power device, caused by a first gate drive voltage during the present switching cycle, is sensed. Based on a second drive signal to be used in the next switching cycle, a second current is determined for that second drive signal, which are then compared to an EMC model. The EMC model defines a plurality of EMC values for respective gate drive voltages and currents conducted through the semiconductor power device. A gate drive voltage adjustment value is selected from a plurality of gate drive voltage adjustment values in the EMC model based on the predicted EMC value generated by the semiconductor power device when being driven using the second drive voltage and conducting the second current. The second gate drive voltage is adjusted using the selected gate drive voltage adjustment value for the next switching cycle.

The gate drive voltage adjustment value may be selected such that the predicted EMC value is below a threshold value for the next switching cycle, that is, the EMC generated by the semiconductor power device during the next switching cycle forms a limit under which levels the semiconductor power device may operate, and the adjustment values are chosen to keep the semiconductor power device operating below the EMC threshold.

The simple low cost approach described in the present invention is counterintuitive to electric machine controller designers who would typically seek to control and minimise losses during switching whilst maximising switch speed albeit within limitations of EMC regulations. In contrast the present invention optimises motor output controlled on the basis of EMI regulated levels which control method may allow increased losses in semiconductor switches through slowing switch rates. An advantage of this approach is changes to EMI regulations can be effected by software updates to controllers without the need for costly component changes..

In more detail, we will describe a gate driver and method that controls the gate driver voltage on one or more power semiconductor switch devices exemplified here by IGBT gates to provide optimal switching speed and conduction loss based on the predicted current that will flow through the IGBT in the next switching interval. Whilst we discuss IGBTs as an example semiconductor power device, of course other power devices may be used in their place, for example Silicon carbide (SiC) semiconducting switch devices, metal oxide semiconducting field effect transistors (MOSFETs), or power diodes.

Such a gate driver removes the need to change individual gate resistances to vary switch rate; a common previously used approach, by enabling predictive real time scaling of the gate drive voltage thus modifying the slew rate delivered by the gate drive circuit. Such a gate driver suits a buffer stage providing the significant advantage of being able to drive multiple IGBTs in parallel.

Alternative approaches to control gate driver waveforms have employed separate circuits to adjust gate charging, onset charging and steady state conditions thereby increasing circuit complexity and cost and increasing the likelihood of device failure. There is significant advantage offered by the described gate driver in using microprocessor(s) as controllers to compute appropriate gate driver voltage waveforms in reducing component count (and thereby cost), complexity and increasing ruggedness.

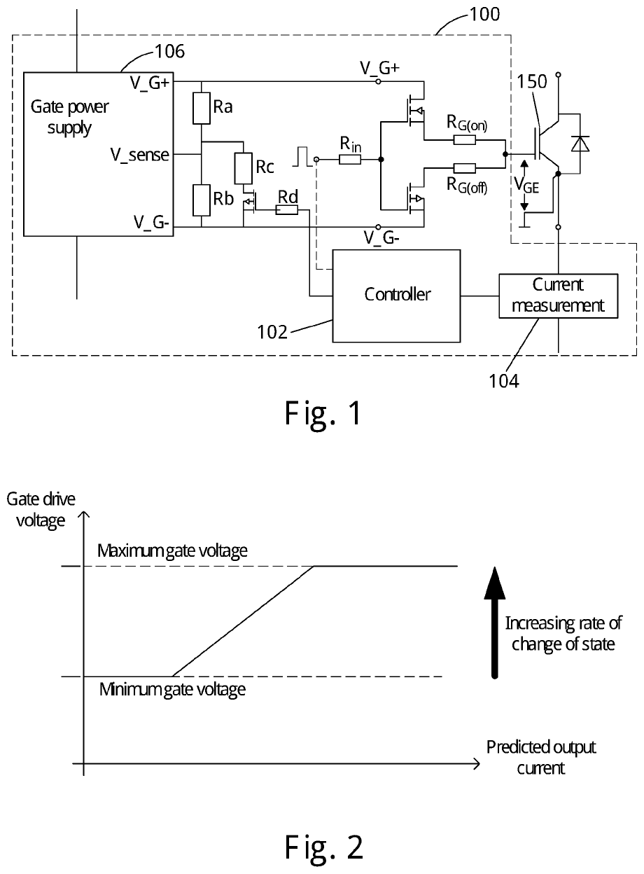

With reference to FIG. 1, the gate driver 100 comprises a controller (such as a microprocessor) 102 within each gate circuit. The controller 102, amongst other things, monitors the semiconductor power device's 150 temperatures and current sharing. The controller 102 also provides a measurement of load output currents from the current sensor 104.

The gate power supply 106 is preferably an SMPS (switched mode power supply) current source with a voltage feedback loop. Current is supplied to the gate on resistor R_{G(on)} and gate off resistor R_{G(off)}, which produces a suitable drive voltage at the gate of the semiconductor power device 150 when an appropriate drive voltage is applied via Rᵢₙ. The slew rate of the semiconductor power device is determined by V_{G+} and V_{G-}, i.e. the supply rails of the gate power supply 106.

A voltage feedback of the gate power supply is provided via a potential divider Rₐ and R_{b}. The actual gate supply voltage V_{G+} and V_{G-} may be varied by changing the ratio of the voltage sensing potential divider R_{c}, which is coupled to a V_sense of the gate power supply 106. The ratio is controlled by the controller 102 via R_{d}.

The controller measures the local output current of the semiconductor power device and uses these sample measurements and knowledge of the next switching pattern (i.e. a desired power required by from the semiconductor power device) to predict the next level of current demand. Based on this predicted current level, an EMC model (in its simplest form a look up table, although it may also be an equation or even a simple threshold for deciding fast and slow switching transition modes) is used to decided how to change the ratio of the voltage sensing potential divider and hence the gate voltage. That is, how to adjust the gate drive voltage in order to ensure the switching of the semiconductor power device stays within the limits of the EMC requirements for the next switching cycle.

The EMC model is based on switch and load current characteristics designed to give maximum switching efficiency limited by EMC regulations. This control approach to power semiconductor switches is particularly useful as increasing numbers of electric vehicles take to the roads and EMC rises in importance as EM noise levels inevitably rise.

Whilst FIG. 1 shows one controller and one semiconductor power devices, the present invention may be scaled up. For example in large power devices, a power switch may comprise a plurality of semiconductor power devices. In such circumstances, the plurality of semiconductor power devices may be connected to one or more of the gate drivers 100, or each gate driver 100 may comprise one or more controllers 102.

For example, in the case of an inverter, a controller 102 is preferably employed for each inverter switch (where many power semiconductor devices in parallel may make up that switch). For example, for a three phase two level inverter there will be six microprocessors, all synchronised by a common clock frequency. For any one switch there may be one or more semiconductor power devices required depending on load current demand and where more than one semiconducting devices are employed they will likely be connected in parallel to enable capacity and their “gates” driven by a single gate driver command provided by a buffer stage.

With reference to FIG. 2 there is shown a representative relationship between the predicted output current and the level of gate voltage. A lower gate voltage (i.e. lower V_{G+} and V_{G-}) provides a softer switching (slower rate of transition). A higher gate voltage provides a harder switching (faster rate of transition). The faster the rate of transition, the greater the value of EMC that is produced by the switches in the power device.

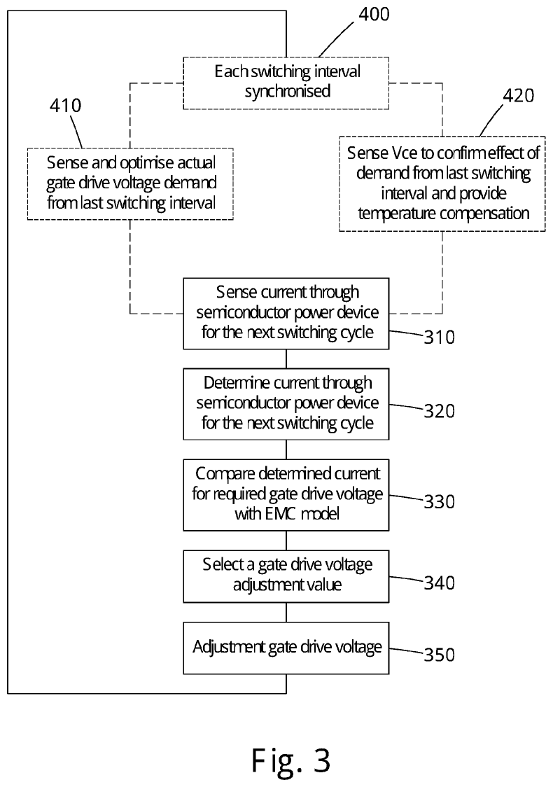

With reference to FIG. 3, we will now describe the steps of the method of controlling the gate of the semiconductor power device according to the present invention.

In its simplest form, the method comprises the following steps:

The current is first sensed in step 310. This first current is as a result of the semiconductor power device being driven, during the present switching cycle, by a first gate drive voltage.

In practice, due to a functional safety requirement for electric vehicle control systems, a comparison of control system current supply 310 using multiple sensing methods is provided. Lack of parity implies a problem and the control system can take appropriate action. Depending on where current sensors are placed it is also possible to determine current sharing characteristics and adjust switching parameters to evenly distribute load current through multiple parallel switches.

In step 320, a second current conducted by the semiconductor power device based on a second gate drive voltage to drive the gate of the semiconductor power device for a next switching cycle is determined.

Present power supply and load characteristics is provided as data to the controller 102 including load and switch currents, drive voltage and semiconductor power device temperature(s). Also provided is data regarding the power required for the next switching cycle based on demand required. From these data it determines or predicts the current demand during the next switching interval, which determines the shape of the voltage waveform presented by the gate driver power supply.

From the determined second current required for the next switching cycle, and based on knowledge of the drive signal required to achieve this, the method then compares these with an Electromagnetic Compliance (EMC) model in step 330. The EMC model defines a plurality of EMC values for respective gate drive voltages and currents conducted through the semiconductor power device. In its simplest form, the EMC model is a look up table of parameters with similar characteristics, although in other forms it may be an equation or even a simple threshold for fast and slow switch transitions.

A gate drive voltage adjustment value is selected from a plurality of gate drive voltage adjustment values in the EMC model in step 340, and the second gate drive voltage is adjusted using the selected gate drive voltage adjustment value in step 350.

The gate drive voltage adjustment value is selected from a plurality of gate drive voltage adjustment values in the EMC model based on the predicted EMC value generated by the semiconductor power device when being driven using the second drive voltage and conducting the second current.

As such, the gate drive voltage is modified to stay within bounds set by EMC requirements whilst maximising transition speed and minimising power losses during switching. Modifying gate drive voltage based on EMC limits is a significant advantage as there is always a compromise on switching speed and the limit is ultimately set by EMC requirements (laws or regulations) which are now being used to govern gate driver characteristics.

The cycle repeats for the subsequent switching cycles.

However, when using the above method with multiple gate drivers 100 or controllers 102 (as described with reference to FIG. 1), the method may comprise additional steps.

As an example, consider a system comprising a three phase inverter power supply requiring a clock 400 to orchestrate six controllers governing each gate driver thereby enabling synchronised switching events with a preferred time delay to produce a suitable phase output e.g. an AC 3-phase sinusoidal supply output into a 3-phase inductive load.

Several sensor inputs provide data to the microprocessors to compute the next gate drive voltage level and the first of these inputs 410 is actual gate drive voltage demand from the last switching interval giving a sense of direction of travel and an ability to offset the next value to optimise tuning

A sensor input 420 may also be taken of collector emitter voltage to confirm the effect of the last switching interval and provide temperature compensation.

It is usually the case that semiconductor and passive device characteristics change with temperature and therefore temperature compensation is an advantageous function offered by gate drive circuity of the present invention.

Whilst we discuss above the gate drive voltage adjustment value being selected based on EMC value limits, it may also be selected based on a predicted slew rate of the semiconductor power device for the second current and second gate drive voltage.

Furthermore, the controller 102 may be configured to generate the gate drive voltage in the first place, as shown in the dashed line in FIG. 1.

No doubt many other effective alternatives will occur to the skilled person. It will be understood that the invention is not limited to the described embodiments and encompasses modifications apparent to those skilled in the art lying within the scope of the claims appended hereto.

1. A gate driver for driving the gate of a semiconductor power device, comprising:
a gate power supply for supplying power to the gate of the semiconductor power device;
a gate input for receiving a gate drive signal;
one or more current sensors for sensing the current flowing through the semiconductor power device;
a controller having an input coupled to the one or more current sensors for receiving a measurement of the current flowing through the semiconductor power device, and an output coupled to the gate power supply for controlling the gate power supply, wherein the controller is configured to:
sense a first current flowing through the semiconductor power device during the present switching cycle when the gate of the semiconductor power device is driven with a first gate drive voltage;
determine a second current conducted by the semiconductor power device based on a second gate drive voltage to drive the gate of the semiconductor power device for a next switching cycle;
compare the second current with an Electromagnetic Compliance (EMC) model, the EMC model defining a plurality of EMC values for respective gate drive voltages and currents conducted through the semiconductor power device;
selecting a gate drive voltage adjustment value from a plurality of gate drive voltage adjustment values in the EMC model;
adjusting the second gate drive voltage using the selected gate drive voltage adjustment value for the next switching cycle,
wherein the gate drive voltage adjustment value is selected from a plurality of gate drive voltage adjustment values in the EMC model based on the predicted EMC value generated by the semiconductor power device when being driven using the second drive voltage and conducting the second current.

2. A gate driver according to claim 1, wherein the gate drive voltage adjustment value is selected such that the predicted EMC value is below a threshold value.

3. A gate driver according to claim 1, wherein the gate drive voltage adjustment value is selected to maximise a transition speed of the semiconductor power device and/or minimise power losses within the semiconductor power device.

4. A gate driver according claim 1, wherein the second gate drive voltage is adjusted by controlling a voltage supplied to the gate of the semiconductor power device by the gate power supply.

5. A gate driver according to claim 4, wherein the gate power supply comprises a current source having a voltage feedback loop, and wherein the second gate drive voltage is adjusted by controlling a voltage on the voltage feedback loop.

6. A gate driver according to claim 4 or 5, wherein controlling the voltage supplied to the gate of the semiconductor power device by the gate power supply adjusts the slew rate of the semiconductor power device.

7. A gate driver according to claim 1, prior to the present switching cycle in which the gate of the semiconductor power device is driven with the first gate drive voltage, the controller is configured to: sense the current flowing through the semiconductor power device due to a gate drive voltage applied to the semiconductor power device gate in the previous switching cycle.

8. A gate driver according to claim 7, wherein the controller is configure to:
compare the current flowing through the semiconductor power device due to a gate drive voltage applied to the semiconductor power device gate in the previous switching cycle to expected values from the EMC model for the same current and drive voltage;
determine a difference between the current flowing through the semiconductor power device due to a gate drive voltage applied to the semiconductor power device gate and the expected values from the EMC model, and
using the difference between the current flowing through the semiconductor power device due to a gate drive voltage applied to the semiconductor power device gate and the expected values from the EMC model in order to adjust the gate drive voltage in a later switching cycle.

9. A gate driver according to claim 1, prior to the present switching cycle in which the gate of the semiconductor power device is driven with the first gate drive voltage, the controller is configured to:
sense the voltage between the collector and emitter of the semiconductor power device due to the gate drive voltage applied to the semiconductor power device gate in the previous switching cycle, and
compensate for a temperature of the semiconductor device based on the sensed voltage between the collector and emitter, by adjusting the gate power supply voltage based on the sensed voltage between the collector and emitter.

10. A gate driver according to claim 1, wherein when there are more than one current sensor, the controller is configured to compare the sensed currents from each of the current sensors and control the gate voltage power supply in response to the compared sensed currents.

11. A gate driver according to claim 1, wherein:
the first current flowing through the semiconductor power device during the present switching cycle when the gate of the semiconductor power device is driven with a first gate drive voltage represents a first power demanded of the semiconductor power device during the present switching cycle;
the determined second current conducted by the semiconductor power device due to the second gate drive voltage to drive the gate of the semiconductor power device for a next switching cycle represents a second power demanded of the semiconductor power device during the next switching cycle.

12. A gate driver according to claim 11, wherein the first and second powers demanded of the semiconductor power device are different.

13. A gate driver according to claim 1, wherein the gate drive voltage adjustment value is additionally selected based on a predicted slew rate of the semiconductor power device for the second current and second gate drive voltage.

14. A gate driver according to claim 1, wherein the controller is configured to generate the gate drive voltage.

15. A power system, comprising:
a plurality of semiconductor power devices configured as one or more power switches; and
a plurality of gate drivers according to any one of claims 1 to 14, each gate driver for driving the gate of respective one or more of the semiconductor power devices.

16. A power system according to claim 15, wherein the plurality of controllers of the plurality of gate drivers are synchronised with a common clock.

17. A power system according to claim 15, wherein the plurality of semiconductor power devices are configured as a multi-phase and/or multi-power-level inverter.

18. A power system according to claim 17, wherein the power system comprises six controllers, and wherein the semiconductor power devices are configured in a three-phase two-level inverter.

19. A power system according to claim 17, wherein the power system comprises six power switches, each of the six controllers being coupled to a respective one of the six power switches, each power switch comprising one or more semiconductor power devices.

20. A method of driving the gate of a semiconductor power device, comprising:
driving the gate of the semiconductor power device with a first gate drive voltage such that it conducts a first current during the present switching cycle;
sensing the first current flowing through the semiconductor power device during the present switching cycle;
determining a second current conducted by the semiconductor power device based on a second gate drive voltage to drive the gate of the semiconductor power device for a next switching cycle;
comparing the second current with an Electromagnetic Compliance (EMC) model, the EMC model defining a plurality of EMC values for respective gate drive voltages and currents conducted through the semiconductor power device;
selecting a gate drive voltage adjustment value from a plurality of gate drive voltage adjustment values in the EMC model;
adjusting the second gate drive voltage using the selected gate drive voltage adjustment value; and
driving the gate of the semiconductor power device using the adjusted second gate drive voltage,
wherein the gate drive voltage adjustment value is selected from a plurality of gate drive voltage adjustment values in the EMC model based on the predicted EMC value generated by the semiconductor power device when being driven using the second drive voltage and conducting the second current.

21. A method according to claim 20, wherein the gate drive voltage adjustment value is selected such that the predicted EMC value is below a threshold value.

22. A method according to claim 20, wherein the gate drive voltage adjustment value is selected to maximise a transition speed of the semiconductor power device and/or minimise power losses with the semiconductor power device.

23. A method according to claim 20, wherein the second gate drive voltage is adjusted by controlling a voltage supplied to the gate of the semiconductor power device.

24. A method according to claim 23, wherein controlling the voltage supplied to the gate of the semiconductor power device by the gate power supply adjusts the slew rate of the semiconductor power device.

25. A method according to claim 20, wherein prior to driving the gate of the semiconductor power device with the first gate drive voltage, the method comprises: sensing the current flowing through the semiconductor power device due to a gate drive voltage applied to the semiconductor power device gate in the previous switching cycle.

26. A method according to claim 25, comprising:
comparing the current flowing through the semiconductor power device due to a gate drive voltage applied to the semiconductor power device gate in the previous switching cycle to expected values from the EMC model;
determining a difference between the current flowing through the semiconductor power device due to a gate drive voltage applied to the semiconductor power device gate and the expected values from the EMC model, and
using the difference between the current flowing through the semiconductor power device due to a gate drive voltage applied to the semiconductor power device gate and the expected values in from the EMC model in order to adjust the gate drive voltage in a later switching cycle.

27. A method according to claim 20, wherein prior to driving the gate of the semiconductor power device with the first gate drive voltage, the method comprises:
sensing the voltage between the collector and emitter of the semiconductor power device due to a gate drive voltage applied to the semiconductor power device gate in the previous switching cycle, and
compensating for a temperature of the semiconductor device based on the sensed voltage between the collector and emitter, comprising:
adjusting the gate voltage based on the sensed voltage between the collector and emitter.

28. A method according to claim 20, wherein sensing the first current flowing through the semiconductor power device during the present switching cycle comprises sensing the current in one or more locations within a circuit comprising the semiconductor power device.

29. A method of driving the gates of a plurality of semiconductor power devices, comprising, for each of the gates for each of the semiconductor power devices, performing the method of driving the gate of a semiconductor power device according to claim 20.

30. A method according to claim 29, wherein the method is performed by a plurality of controllers, each controller being associated with a respective one or more of the plurality of semiconductor power devices.

31. A method according to claim 30, wherein the plurality of controllers are synchronised with a common clock.

32. A method according to claim 20, wherein:
the first current flowing through the semiconductor power device during the present switching cycle when the gate of the semiconductor power device is driven with a first gate drive voltage represents a first power demanded of the semiconductor power device during the present switching cycle, and
the determined second current conducted by the semiconductor power device due to the second gate drive voltage to drive the gate of the semiconductor power device for the next switching cycle represents a second power demanded of the semiconductor power device during the next switching cycle.

33. A method according 32, wherein the first and second powers demanded of the semiconductor power device are different.

34. A method according to claim 20, wherein the gate drive voltage adjustment value is additionally selected based on a predicted slew rate of the semiconductor power device for the second current and second gate drive voltage.

35. A method according to claim 20, comprising generating the gate drive voltage, and driving the gate of the semiconductor power device with the gate drive voltage.

36. A gate driver according to claim 1, a power system according to claim 15, or a method according to claim 20, wherein the semiconductor power device comprises an IGBT, Silicon carbide (SiC) semiconducting switch devices, metal oxide semiconducting field effect transistors (MOSFETs), or power diodes.
